(19) United States
(12) Patent Application Publication
(10) Pub. No.: US 2024/0397665 A1
(43) Pub. Date: Nov. 28, 2024

(54) ELECTRONIC DEVICES WITH A LOOPED THERMAL MODULE HAVING A UNIDIRECTIONAL VALVE

(71) Applicant: Apple Inc., Cupertino, CA (US)

(72) Inventors: Jifang TIAN, Fremont, CA (US); Anthony J. AIELLO, Santa Cruz, CA (US); Arash NAGHIB LAHOUTI, San Jose, CA (US); Cheng P. TAN, Fremont, CA (US)

(21) Appl. No.: 18/202,229

(22) Filed: May 25, 2023

(51) Int. Cl. H05K 7/20

(52) U.S. Cl. CPC H05K 7/20327; H05K 7/20309; H05K 7/20318

(57) ABSTRACT

A thermal module may include a valve used to promote unidirectional flow. The valve may be formed from several flow barriers designed to provide minimal resistance to a refrigerant while flowing in one direction, but provide significant resistance to flow in the opposite direction. The thermal module may include a void. The refrigerant may flow or circulate in a loop around the void. Using the valve for unidirectional flow, a thermal module may provide enhanced thermal transport capabilities.

### TECHNICAL FIELD

This application is directed to thermal modules, and more particularly, to thermal modules with a valve that promotes unidirectional flow.

### BACKGROUND

Electronic devices (e.g., consumer electronic devices) continue to use advanced integrated circuitry (e.g., system on a chip, or SOC) for various complex processing functions. This may cause the integrated circuitry to operate for longer durations and at higher frequencies. As a result, the heat (e.g., thermal energy) generated during operation of the integrated circuitry tends to increase. Current thermal modules (e.g., heat spreaders), relying significantly on thermal conductivity of its components, may lack the necessary thermal transport capabilities.

### BRIEF DESCRIPTION OF THE DRAWINGS

Certain features of the subject technology are set forth in the appended claims. However, for purpose of explanation, several embodiments of the subject technology are set forth in the following figures.

FIG. 1A and FIG. 1B illustrate examples of an electronic device, in accordance with aspects of the present disclosure.

FIG. 2 illustrates an exploded view of an example of a thermal module, in accordance with aspects of the present disclosure.

FIG. 3 illustrates a plan view of a thermal module, in accordance with aspects of the present disclosure.

FIG. 4 illustrates a plan view of several flow barriers used as a valve in a thermal module, in accordance with aspects of the present disclosure.

FIG. 5 illustrates an enlarged view of flow barriers, in accordance with aspects of the present disclosure.

FIG. 6 and FIG. 7 illustrate flow barriers and vapor flow through the flow barriers in different directions, in accordance with aspects of the present disclosure.

FIG. 8A, FIG. 8B, and FIG. 8C illustrate cross sectional views of various features such as flow barriers, pillars, and wicks of a thermal module, in accordance with aspects of the present disclosure.

FIG. 9 illustrates an example of a thermal module that includes channels, in accordance with aspects of the present disclosure.

FIG. 10 illustrates a cross sectional view of the thermal module shown in FIG. 9, showing respective heights of structures within the channels, in accordance with aspects of the present disclosure.

FIG. 11 and FIG. 12 illustrate examples of a thermal module that includes channels, in accordance with aspects of the present disclosure.

FIG. 13 and FIG. 14 illustrate examples of a thermal module with multiple openings, in accordance with aspects of the present disclosure.

FIG. 15 illustrates a block diagram of a thermal module with a pump, in accordance with aspects of the present disclosure.

FIG. 16A and FIG. 16B illustrate an alternate example of a flow barrier, in accordance with aspects of the present disclosure.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

The subject technology is directed to thermal modules that promote unidirectional, or one-way, flow of substances, such as liquids and vapor, used to transport heat. Thermal modules described herein may include several flow barriers that take the form of stationary structures (e.g., stationary flow barriers) extending from a base or housing part. The flow barriers may take the shape of a herringbone, a chevron, or a V-shape, as non-limiting examples. Collectively, the flow barriers may function as a valve (e.g., one-way valve, check valve) that promotes a unidirectional and uniform flow of a refrigerant used to transport heat. Additionally, thermal modules described herein may include one or more voids. The flow barriers may cause vapor to circulate, or flow around, the void in a loop. Based in part on the flow barriers causing the unidirectional flow, thermal modules described herein may provide a thermal transport capacity, Qₘₐₓ (in Watts per meter-degree), several times greater than traditional thermal modules. Beneficially, thermal modules described herein may be used in more thermal applications in which heat generation (e.g., in electronic devices) becomes increasingly higher, and where space constraints limit the use of conventional thermal modules of comparable thermal transport capacity.

Based in part on the shape and spacing of the flow barriers, the refrigerant, in a gas state (e.g., vapor, gaseous state, gas phase), can flow around the flow barriers with minimal restriction provided by the flow barriers. However, when the refrigerant flows in the opposite direction, the flow barriers may block or substantially restrict the flow. In this regard, the flow barriers provide a pressure differential that causes flow bias in an intended direction, thus limiting the flow to a (generally) single direction.

Thermal modules described herein may include additional features. For example, a thermal module may include an evaporator section that receives heat and causes (based on the received heat) a phase change of a refrigerant from a liquid state (e.g., liquid phase) to a gas state. In the gas state, the refrigerant may flow as pressurized vapor from the evaporator region through an additional, intermediate section to a condensation section, where the heat is dissipated from the refrigerant and converted back to its liquid state. Based in part on causing a flow bias, the flow barriers may cause the refrigerant to flow in one general direction (thus preventing or limiting flow in the opposite direction) from the evaporator section to the condensation section via the intermediate section. The condensation section is designed to condense the refrigerant from the gas state to the liquid state. However, in the condensation section, when some of the refrigerant is still in the liquid state, the refrigerant may take the form of a liquid-vapor mixture, e.g., a mix of refrigerant in the liquid and gas states. The refrigerant may be transported the refrigerant to the evaporator section via capillary wicking through, for example, the valve, with the pressurized vapor from the refrigerant in the gas state and the capillary pressure in the valve providing a force to push the refrigerant. Additionally, one or more wick structures may provide additional capillary pressure. Thus, the refrigerant may circulate in a unidirectional, two-phase (e.g., gas and liquid) cooling loop through the thermal module.

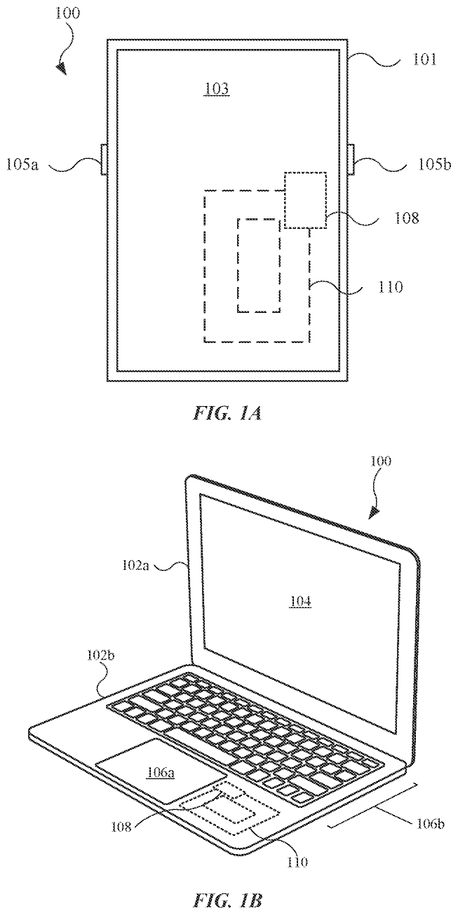

These and other embodiments are discussed below with reference to FIGS. 1-16B. However, those skilled in the art will readily appreciate that the detailed description given herein with respect to these Figures is for explanatory purposes only and should not be construed as limiting.

According to some embodiments, for example as shown in FIG. 1A, an electronic device 100 takes the form of a mobile wireless communication device, such as a smartphone or a tablet computing device, as non-limiting examples. As shown, electronic device 100 includes a housing 101 and a display 103 coupled to housing 101. Housing 101 may include metal (including metal alloy), a transparent material (e.g., glass sapphire), or a combination thereof. Display 103 is designed to present visual information, such as textual information, still images, or motion images (e.g., video). Further, display 103 may include a capacitive touch sensitive layer, thus allowing display 103 to receive touch inputs and/or gestures through interaction with display 103.

Electronic device 100 may further include one or more buttons. For example, electronic device 100 included a button 105a and a button 105b, each of which can be depressed to provide an input to, for example, interact with and alter/update the visual information on display 103. Although buttons 105a and 105b are shown in particular locations, buttons 105a and 105b may generally be positioned in other locations. Also, although buttons 105a and 105b represent a discrete number of buttons, electronic device 100 may include a different number of buttons.

Electronic device 100 may further include a circuit board (not shown in FIG. 1) on which heat-generating component 108 is located. In order to draw heat away from heat-generating component 108, electronic device 100 may further include a thermal module 110 (representing one or more thermal modules) that is thermally coupled to heat-generating component 108. Heat-generating component 108 may take the form of processing circuitry, which may include a central processing unit, a graphics processing unit, one or more microcontrollers, an application-specific integrated circuit, or a combination thereof. In some examples, thermal module 110 is a heat spreader. In this regard, thermal module 110 may take the form of a vapor chamber. Thermal module 110 is designed to transport heat generated by heat-generating component 108 from, for example, one location of thermal module 110 to another, different location of thermal module 110, where the transported heat can be dissipated and/or expelled from electronic device 100. For example, electronic device 100 may include a heatsink (not shown in FIG. 1) thermally coupled to thermal module 110, with the heatsink designed to remove heat from thermal module 110. Also, although not expressly shown, electronic device 100 may include one or more additional thermal modules with similar or different shapes and sizes, as compared to thermal module 110.

Referring to FIG. 1B, an electronic device 100 takes the form of a laptop computing device. Electronic device 100 may include a housing component 102a (e.g., display housing) and a housing component 102b (e.g., base). The housing components 102a and 102b may be rotationally coupled together, thus allowing relative rotational movement between housing components 102a and 102b. As shown, housing component 102a carries a display 104 designed to present visual information (e.g., textual information, still images, video images, or a combination thereof), while housing component 102b carries an input mechanism 106a (e.g., track pad) and an input mechanism 106b (e.g., keyboard).

Additionally, electronic device 100 may include processing circuitry connected (e.g., electrically connected) to display 104 and input mechanisms 106a and 106b. In this regard, electronic device 100 may include a heat-generating component 108 Electronic device 100 may further include a circuit board (not shown in FIG. 1) on which heat-generating component 108 is located. In order to draw heat away from heat-generating component 108, electronic device 100 may further include a thermal module 110 (representing one or more thermal modules) that is thermally coupled to heat-generating component 108. Heat-generating component 108 and thermal module 110 may include any features shown and described herein for a heat-generating component and a thermal module, respectively.

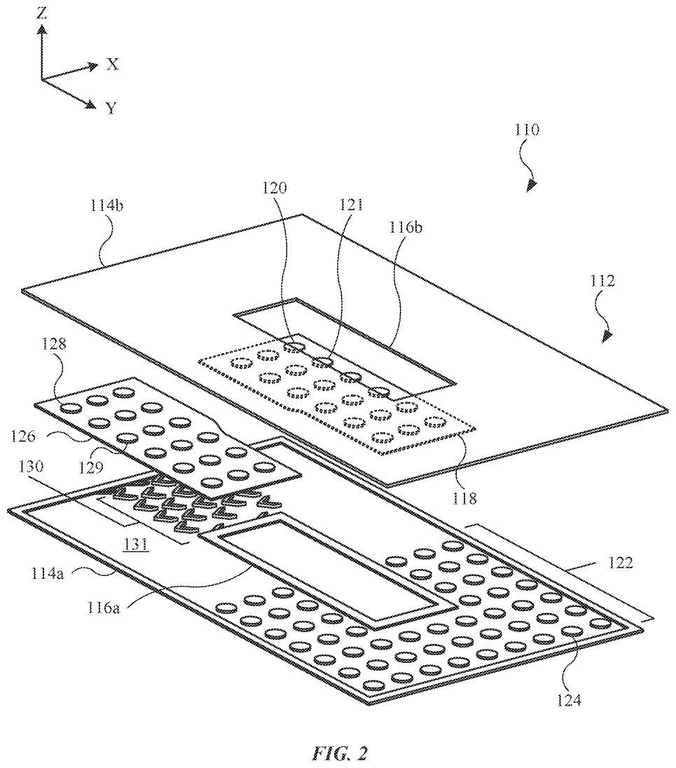

Referring to FIG. 2, an exploded view of thermal module 110 is shown. Thermal module 110 may include an enclosure 112, or housing. Enclosure 112, defining an outer perimeter of thermal module 110, may include a width (along the X-axis of Cartesian coordinates) approximately in the range of 40 to 75 millimeters (mm). Enclosure 112 may include a length (along the Y-axis of Cartesian coordinates) approximately in the range of 140 to 160 mm. Enclosure 112 may include a length (along the Z-axis of Cartesian coordinates) approximately in the range of 0.2 to 0.5 mm. Accordingly, based on dimensional information, enclosure 112 may include a rectangular enclosure. However, other shapes are possible.

Enclosure 112 may include a part 114a, or base, and a part 114b, or cover. Also, each of parts 114a and 114b may be referred to as a housing part. In some examples, each of parts 114a and 114b includes a metal, such as copper or copper alloy (as non-limiting examples). Also, each of parts 114a and 114b may include an opening 116a and an opening 116b, respectively. Thus, when parts 114a and 114b are combined, enclosure 112 may form a closed loop flow passage around a void, or opening, defined by openings 116a and 116b.

Parts 114a and 114b may combine to enclose and store several components and structural features of thermal module 110. For example, thermal module 110 may include an evaporator section 118. When inserted into an electronic device (not shown in FIG. 2), thermal module 110 may be thermally coupled to one or more heat-generating components. In particular, evaporator section 118 may be positioned in proximity to the one or more heat-generating components. As a result, a refrigerant (not shown in FIG. 2) located at or near evaporator section 118 may receive at least some of the heat from the one or more heat-generating components and change from phase, e.g., change from a liquid phase (e.g., liquid state) to as gas phase (e.g., gas state). Evaporator section 118 may include several pillars. For example, evaporator section 118 may include a pillar 120a (representative of several additional pillars) designed to provide a standoff for structural support at evaporator section 118, thus maintaining a gap between parts 114a and 114b and allowing a refrigerant (e.g. in a gas state) can pass in a clearance between parts 114a and 114b, as well as between adjacent pillars. When functioning as a standoff, pillar 120a ensure part 114b does not collapse (e.g., onto part 114a) and close off the flow path. Additionally, evaporator section 118 may further include a wick structure 121. In some examples, wick structure 121 includes a porous metal structure formed by sintering, as a non-limiting example. As a result, a refrigerant can be drawn in by wick structure 121 through capillary forces and promote movement or flow of the refrigerants, while pillar 120 may promote movement or flow of a refrigerant. Thus, evaporator section 118 may include a combination of pillars and wick structures. In one or more implementations, a wick structure (e.g., wick structure 121) also functions as a pillar extending from part 114a to support part 114b. While pillar 120a and wick structure 121 generally take the form of a cylindrical column, other shapes are possible.

Thermal module 110 may further include an intermediate section 122 that receives a refrigerant from evaporator section 118. Intermediate section 122 may be referred to as a vapor travel section. As shown, intermediate section 122 may include several pillars. For example, intermediate section 122 may include a pillar 124 (representative of several additional pillars). Pillars 124 may be used as standoffs to maintain the gap between the part 114a and the part 114b for refrigerant flow passage. As a result, when parts 114a and 114b are secured together, pillar 124, as well as other pillars extending from part 114a, engage part 114b. Also, pillars 124 may be formed by etching (e.g., laser etching) part 114a or by additive manufacturing (e.g., three-dimensional printing) onto part 114a, as non-limiting examples.

Thermal module 110 may further include a condensation section 126. Condensation section 126 may represent a location in which a refrigerant in the gas state is cooled and converted to a liquid state. In this regard, condensation section 126 may be placed in proximity to thermal component (e.g., heatsink) used to dissipate heat from thermal module 110 at condensation section 126. Condensation section 126 may include several pillars. For example, condensation section 126 may include a pillar 128 (representative of several additional pillars). Similar to pillar 120a, pillar 128 may provide a for structural support at condensation section 126, thus maintaining a gap between parts 114a and 114b and allowing a refrigerant (e.g. in a gas state) can pass in a clearance between parts 114a and 114b, as well as between adjacent pillars. Additionally, condensation section 126 may further include a wick structure 121. Similar to wick structure 121, wick structure 129 includes a porous metal structure formed by sintering, as a non-limiting example. As a result, a refrigerant can be drawn in by wick structure 129 through capillary forces and promote movement or flow of the refrigerants, while pillar 128 may promote movement or flow of a refrigerant. While pillar 128 and wick structure 129 generally take the form of a cylindrical column, other shapes are possible.

In one or more implementations, condensation section 126 is designed to condense the refrigerant from the gas state to the liquid state. However, in condensation section 126, when some of the refrigerant is still in the liquid state, the refrigerant may take the form of a liquid-vapor mixture, e.g., a mix of refrigerant in the liquid and gas states. The refrigerant may be transported the refrigerant to evaporator section 118 via flow barriers 130 (discussed below), with the pressurized vapor from the refrigerant in the gas state and the capillary pressure in the valve providing a force to push the refrigerant. Additionally, one or more wick structures (e.g., wick structure 129) may provide additional capillary pressure. Thus, the refrigerant may circulate in a unidirectional, two-phase (e.g., gas and liquid) cooling loop through thermal module 130.

Thermal module 110 may further include flow barriers 130 that extend from a surface 131 of part 114a. As shown, flow barriers 130 may be positioned between condensation section 126 and evaporator section 118. Collectively, flow barriers 130 may be used as a valve (e.g., one-way valve, bias valve, check valve) to regulate flow of a refrigerant. For example, flow barriers 130 may allow a refrigerant to move from condensation section 126 to evaporator section 118. Conversely, however, flow barriers 130 may prevent or substantially limit the refrigerant from directly flowing from evaporator section 118 to condensation section 126 through flow barriers 130. it should be noted that the flow path in the direction from evaporator section 118 to intermediate section 122 is relatively less impeded than the flow path across the flow barriers in a direction from evaporator section 118 to condensation section 126 (e.g., in a reverse direction). As a result, a refrigerant may flow clockwise. This will be further discussed below in more detail. Also, similar to pillars (discussed above), each of flow barriers 130 may be formed by etching (e.g., laser etching, electrochemical machining (ECM), chemical etching, etc.) part 114a or by additive manufacturing (e.g., three-dimensional printing, laser sintering, etc.) onto part 114a, or forming (e.g. stamping), or molding (e.g. thixomolding), as non-limiting examples. Accordingly, each of the flow barriers 130 (as well as other flow barriers shown and/or described herein) may take the form of a stationary structure (e.g., non-moving structures) while collectively acting as a valve.

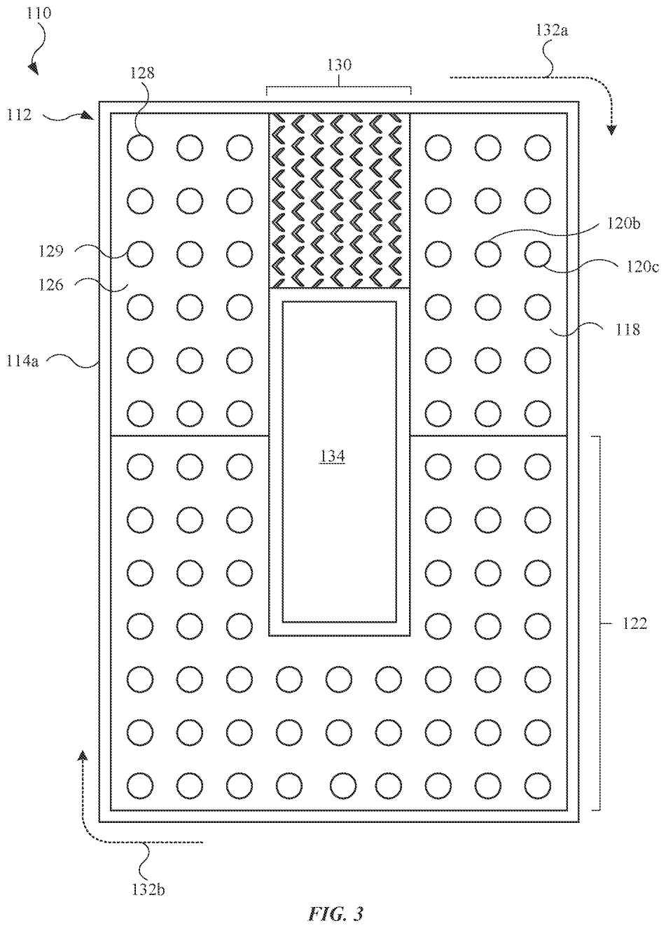

Referring to FIG. 3, thermal module 110 is shown in an assembled state. For purposes of illustration, part 114b (shown in FIG. 2) is removed. An arrow 132a and an arrow 132b around a perimeter of part 114a show a general direction of flow of a refrigerant (not shown in FIG. 3) located within thermal module 110. As shown, a refrigerant will generally flow clockwise in the clearances between the standoffs (e.g., a pillar 120b and a pillar 120c) and through the flow barriers 130, and refrigerant in a gas state that condenses to a liquid state (primarily happening in condensation section 126) will be absorbed into the porous wick structure (e.g., wick structure 121), and flow counterclockwise within the wick structures by capillary force to replenish the refrigerant in the liquid state that is driven off by evaporation in evaporator section 118. Accordingly, a refrigerant may circulate in a clockwise direction around a void 134 of thermal module 110. Void 134 may refer to a portion (e.g., open portion) of thermal module 110 not occupied or enclosed by enclosure 112. As shown, void 134 is surrounded by enclosure 112. When the refrigerant, in a gas state, is located in evaporator section 118, flow barriers 130, acting collectively as a valve, provide a relatively high impedance against the flow of the refrigerant (in a gas state) attempting to flow in a counterclockwise direction (e.g., from evaporation section 118 to condensation section 126), while providing a relatively low impedance for the refrigerant flowing in a clockwise (e.g., opposing) direction. Further, the flow barriers 130 may form a pressure differential on the refrigerant, causing a pressure drop from a location at the evaporator section 118 (shown to the right of flow barriers 130) to a location at condensation section 126 (shown to the left of flow barriers 130). Based on the above-mentioned effect of flow barriers 130, the refrigerant tends to circulate in the direction of arrows 132a and 132b, originating at evaporator section 118, then flowing through intermediate section 122, and subsequently through condensation section 126. When the refrigerant is located at condensation section 126, the refrigerant, in a liquid state, may not experience the same or similar pressure differential at flow barriers 130. As a result, the refrigerant, in a liquid state, may flow more from condensation section 126 to evaporator section 118 through flow barriers 130 with less obstruction and impedance provided by flow barriers 130.

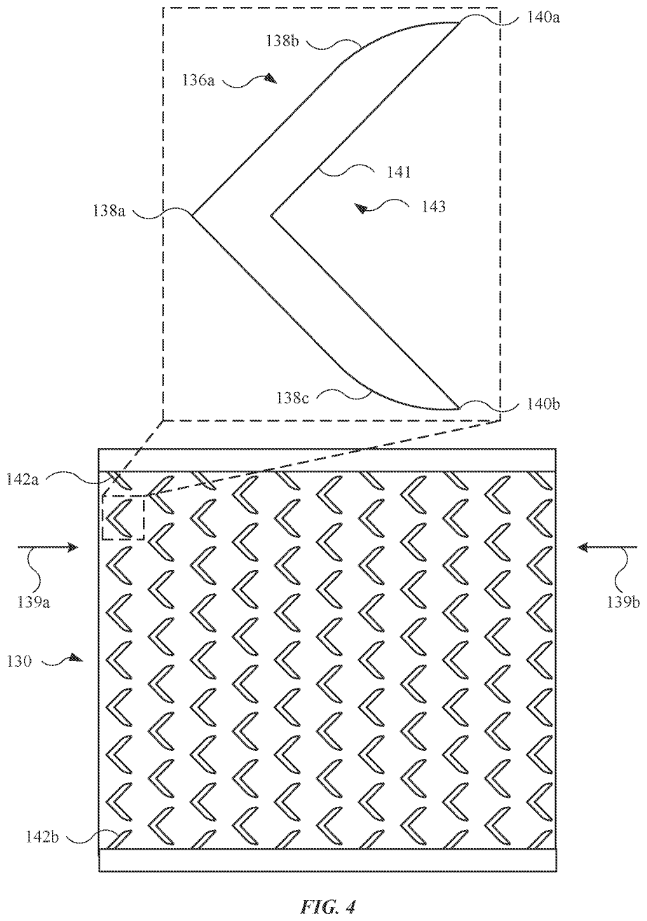

Referring to FIG. 4, a plan view of flow barriers 130 is shown. As shown, flow barriers 130 may be arranged in columns. Further, each column may include flow barriers that are staggered with respect to adjacent columns. This will be discussed further below. As shown in the enlarged view, a flow barrier 136a (representative of the remaining flow barriers) make take on a shape such as a herringbone shape, a chevron, a triangle, or an arrow, as non-limiting examples so long as the shape of flow barrier 136a redirects flow smoothly in one direction, while disrupting flow in the opposite direction. Flow barrier 136a may include a corner 138a that splits a flow into two streams. As shown, corner 138a may form an apex defined by a relatively sharp edge formed at an intersection of two straight sides or portions of flow barrier 136a. Corner 138 may be referred to as a leading edge. Corner 138a may provide flow barrier 136a with an aerodynamically and hydrodynamically favorable shape when flow from a refrigerant (not shown in FIG. 4) moves along an arrow 139a, representing a direction of forward flow or desired directional flow of the refrigerant. Accordingly, corner 138 may face, or generally point toward the oncoming refrigerant flowing in the desired direction. Further, flow barrier 136a may include a corner 138b and a corner 138b, each of which may be defined by a relatively rounded or smooth corner (as compared to corner 138a).

Additionally, flow barrier 136a may include a corner 140a and a corner 140b, each of which may be referred to as an edge and combining to surround a trailing edge 141. As shown, each of corners 140a and 140b may include a relatively sharp corner. Unlike corner 138a, corner 140a 140b, and trailing edge 141 may provide flow barrier 136a with an aerodynamically and hydrodynamically unfavorable shape when flow from a refrigerant (not shown in FIG. 4) moves along a direction of arrow 139b.

Flow barrier 136a may further include a concave portion 143. When a refrigerant flows in a direction of arrow 139b, defining back flow that is generally opposite of the direction of arrow 139a, the refrigerant may become trapped, slowed, or otherwise impeded by flow barrier 136a based on concave portion 143. Further, corners 140a and 140b, each being sharp, may further impede the refrigerant flow along a direction of arrow 139b. As shown in FIG. 4, each of corners 140a and 140b may face, or generally point toward, a direction of back flow.

Additionally, several structures may surround flow barriers 130. For example, a wall 142a and a wall 142b can fill voids or spaces not covered by flow barriers 130. Walls 142a and 142b block a potential leakage path around the sides of the pattern of flow barriers 136a so that bias of a refrigerant flowing along a direction of arrow 139a is not compromised.

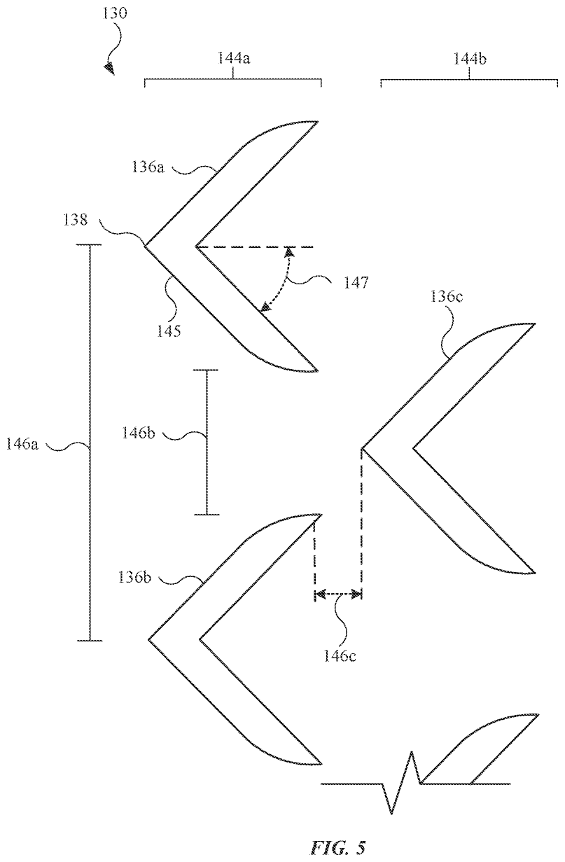

Referring to FIG. 5, an enlarged view of the flow barrier 130 is shown. As shown, a flow barrier 136a and a flow barrier 136b (adjacent to flow barrier 136a) are located in a column 144a, and a flow barrier 136c is located in a column 144b adjacent to column 144a. Additional features for a flow barrier may be present. For example, flow barrier 136a (representative of other flow barriers shown and/or described herein) may include an angle 147 (e.g., apex angle) measured from a corner 138 (or apex) to a leg 145 (representative of an additional leg) of flow barrier 136a. Angle 147 may approximately be in the range of 25 to 65 degrees. In one or more implementations, angle 147 is 45 degrees.

Several spatial relationships among flow barriers 130 are shown. For example, flow barriers 136b and 136c are separated by a dimension 146a (e.g., a pitch dimension representing a one-dimensional direction). Dimension 146a may represent a distance between respective leading edges of flow barriers 136b and 136d. Dimension 146a may represent a pitch, or distance between respective leading edges of flow barriers 136b and 136c. Flow barrier 136d, located in column 144b, may be staggered, or offset, from flow barrier 136b (or flow barrier 136c) by an amount equal to 0.5 of dimension 146a. Accordingly, flow barrier 136d may by staggered by one-half of the pitch between flow barriers 136b and 136c. However, flow barrier 136d may be staggered by other differences. Beneficially, by locating flow barrier 136d at one-half of the pitch, flow barrier 136d is centered between flow barriers 136b and 136c, which may still allow for forward flow of a refrigerant (not shown in FIG. 5), while flow barriers 136b, 136c, and 136d collective block or impede back flow of the refrigerant.

Additionally, flow barriers 136b and 136c may be separated by a dimension 146b (e.g., a gap dimension representing a one-dimensional direction). Dimension 146b may represents a shortest distance between adjacent flow barriers in a column. In some examples, dimension 146b is 0.5 mm. However, dimension 146b may be approximately in the range of 0.25 to 1 mm, as a non-limiting example. The spatial relationships shown and described in FIG. 5 may be representative of those among the remaining flow barriers of flow barrier 130, as well as among other flow barriers shown and/or described herein.

Further, adjacent columns may be separated by a predetermined or predefined dimension. For example, columns 144a and 144b are separated by a dimension 146c. Dimension 146c may approximately be in the range of 0.25 to 2 mm. In one or more implementations, angle 147 is 1 mm.

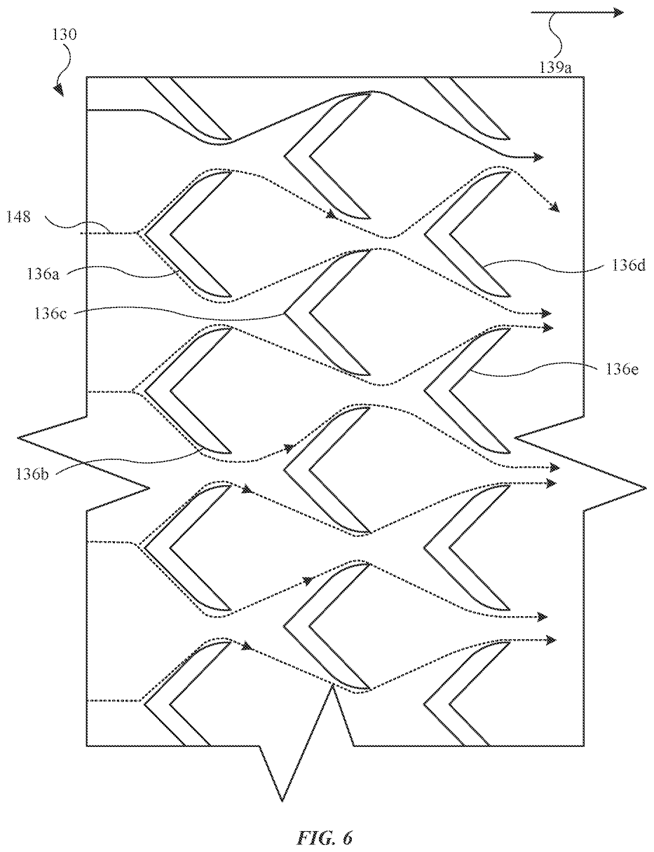

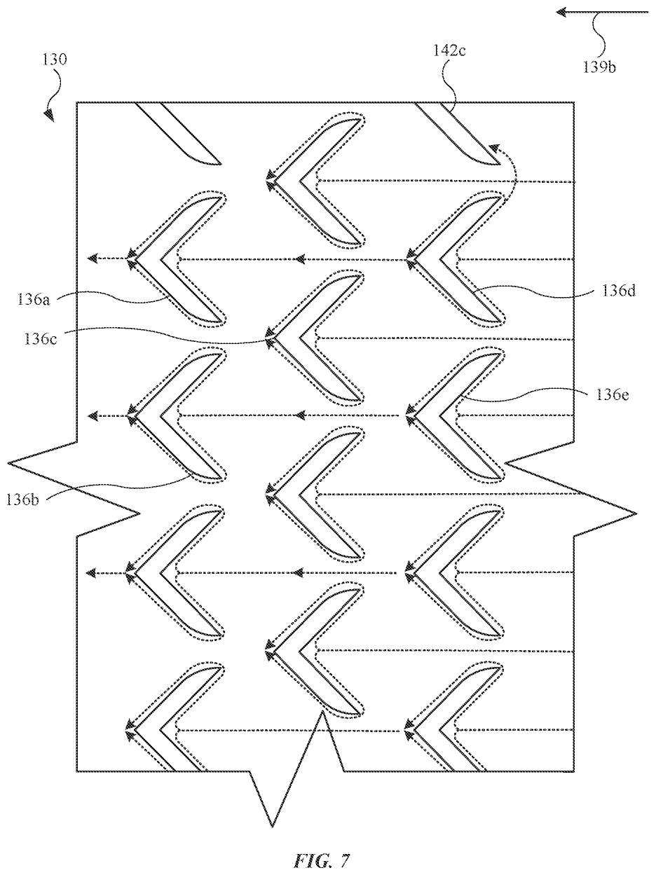

FIGS. 6 and 7 show exemplary flow paths of a refrigerant 148 (represented by dotted lines) through flow barriers 130. Referring to FIG. 6, refrigerant 148 is flowing through flow barriers 130 in a direction of arrow 139a. Accordingly, the flow of refrigerant 148 represents forward flow. When refrigerant 148 reaches flow barriers 136a and 136b, flow barriers 136a and 136b generally allow refrigerant 148 to pass and flow in a direction toward flow barrier 136d. Flow barrier 136c generally allows refrigerant 148 to pass and flow freely in a direction toward a flow barrier 136d and a flow barrier 136e. The exemplary flow of refrigerant 148 may continue through flow barriers 130 with relatively minimal impedance, pressure drop, energy loss, and drag force.

Referring to FIG. 7, refrigerant 148 is flowing through flow barriers 130 in a direction of arrow 139b. Accordingly, the flow of refrigerant 148 represents back flow. When refrigerant 148 reaches flow barriers 136d and 136e, refrigerant 148 may flow into respective concave portions of flow barriers 136d and 136e and around the sharp edges of flow barriers 136d and 136e, which provide resistance and limit or restrict the flow of refrigerant 148. Other shapes of this side of flow barriers, such as the flat third face of a triangle can work too, so long as they have more aerodynamic drag than the shape on the opposite side (e.g. apex shape, bullet shape, etc.). Refrigerant 148 that passes around flow barriers 136d and 136e may flow in a direction toward flow barrier 136c or a wall 142c (representing a partial flow barrier). A concave portion of flow barrier 136d, as well as its relatively sharp corner(s), may provide resistance and limit or restrict the flow of refrigerant 148. The shape and orientation of wall 142c may also provide resistance and limit or restrict the flow of refrigerant 148. Refrigerant 148 that passes around flow barrier 136c may flow in a direction toward flow barriers 136a and 136b, where respective concave portions of flow barriers and sharp corners of flow barriers 136a and 136b may provide resistance and limit or restrict the flow of refrigerant 148. Accordingly, the exemplary flow of refrigerant 148 may continue through flow barriers 130 with relatively high impedance, pressure drop, and/or drag force. In this regard, the flow barriers 130 may function as a one-way valve or a check valve while each flow barrier is not moving. Put another way, each flow barrier of the flow barrier 130 may be referred to as a stationary flow barrier.

In computer-simulated models, a refrigerant may experience more than twice the pressure drop in the back flow direction (e.g., along the direction of arrow 139b in FIG. 7) as compared to that in the forward flow direction (e.g., along the direction of arrow 139a in FIG. 6), indicating that the flow impedance is much greater in the reverse flow or back flow direction. Additionally, a refrigerant may experience more than twice the drag force in the back flow direction (e.g., along the direction of arrow 139b in FIG. 7) as compared to that in the forward flow direction (e.g., along the direction of arrow 139a in FIG. 6). Thus, the models may provide additional indication of the benefits and advantages of the flow barriers 130 providing the functionality of a one-way valve or a check valve to bias refrigerant flow in a preferred direction for a thermal module (e.g., thermal module 110 shown in FIG. 2).

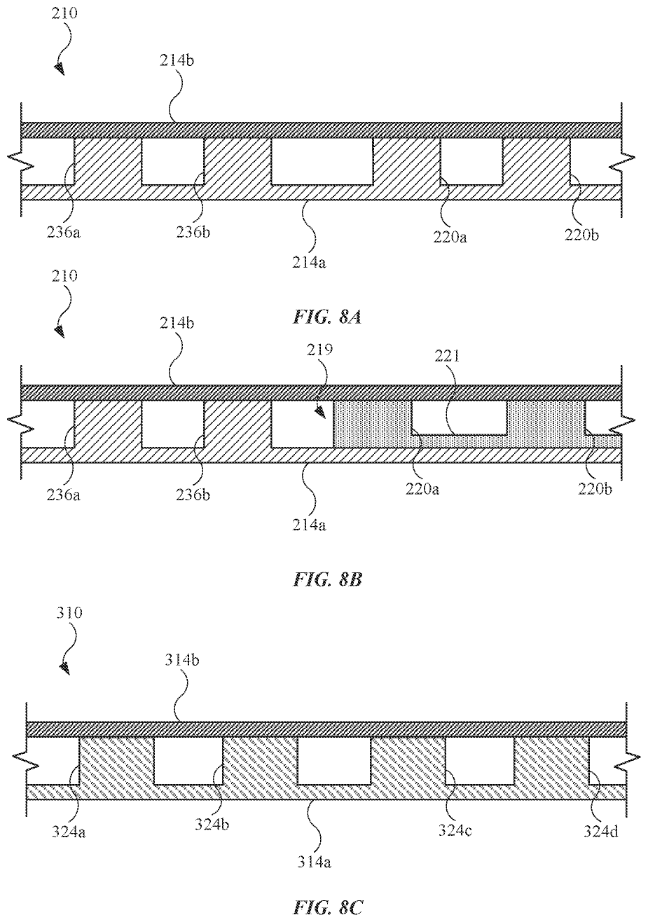

FIGS. 8A-16B show and describe alternate examples of thermal modules. The thermal modules shown and described in FIGS. 8A-16B may include any features previously shown and/or described herein for a thermal module. Additionally, prior examples of thermal modules may be modified with at least some features shown and/or described in FIGS. 8A-16B.

Referring to FIG. 8A, a thermal module 210 includes a part 214a and a part 214b coupled to part 214a. In one or more implementations, parts 214a and 214b include a metal, such as copper. Thermal module 210 may further include a flow barrier 236a and a flow barrier 236b (representative of additional flow barriers used as a valve (e.g., flow barriers 130 shown in FIGS. 2 and 3) for thermal module 210) extending from part 214a and intended to bias flow in a desired direction. Thermal module 210 may further include a pillar 220a and a pillar 220b (representative of additional pillars used in an evaporator section of thermal module 210) extending from part 214a and intended to form structural stiffness for the section containing wick structures within an evaporation section of thermal module 210. As shown, flow barriers 236a and 236b and pillars 220a and 220b extend from, and are integrally formed with (to form a single piece, for example), part 214a. Further, flow barriers 236a and 236b and pillars 220a and 220b engage part 214b, thus providing structural support to part 214b. The phrase “integrally formed” refers to two or more structures formed from a single piece of material, such as a metal or metal alloy.

Alternatively, as shown in FIG. 8B, pillars 220a and 220b may take the form of wick structures, thus providing structural support and a structure for promoting capillary pressure increase of a refrigerant. As shown, pillars 220a and 220b are part of a wick 219. In addition to pillars 220a and 220b, wick 219 may include a wick floor 221 integrated with pillars 220a and 220b. Similar to pillars 220a and 220b, wick floor 221 may include a porous material for promoting capillary pressure increase of a refrigerant. As shown, each of flow barriers 236a and 236b (in a valve made from several flow barriers) as well as each of pillars 220a and 220b may extend from part 214a and contact part 214b, thus supporting part 214b and promoting a space or gap between parts 214a and 214b.

Referring to FIG. 8C, a thermal module 310 includes a part 314a and a part 314b coupled to part 314a. Thermal module 310 includes pillars, such as a pillar 324a, a pillar 324b, a pillar 324c, and a pillar 324d (representative of additional pillars in an intermediate section (e.g., intermediate section 122 shown in FIGS. 2 and 3) of thermal module 210), that extend from part 314a (or a surface of part 314a). As shown, each of pillars 324a, 324b, 324c, and 324d may be integrally formed with, and extending from part 314a to contact part 314b, thus supporting part 314b and promoting a space or gap between parts 314a and 314b. While FIGS. 8A and 8B show respective cross-sectional views with different structures having different markings (e.g., different cross hatches), in one or more implementations, the flow barriers (e.g., flow barriers 236a and 236b shown in FIG. 8A) and/or the pillars (e.g., pillars 220a and 220b shown in FIG. 8A) may be separated pieces that are attached to part 214a. Similarly, in one or more implementations, the pillars (e.g., pillars 324a, 324b, 324c, and 324d shown in FIG. 8C) may be separated pieces that are attached to part 314a.

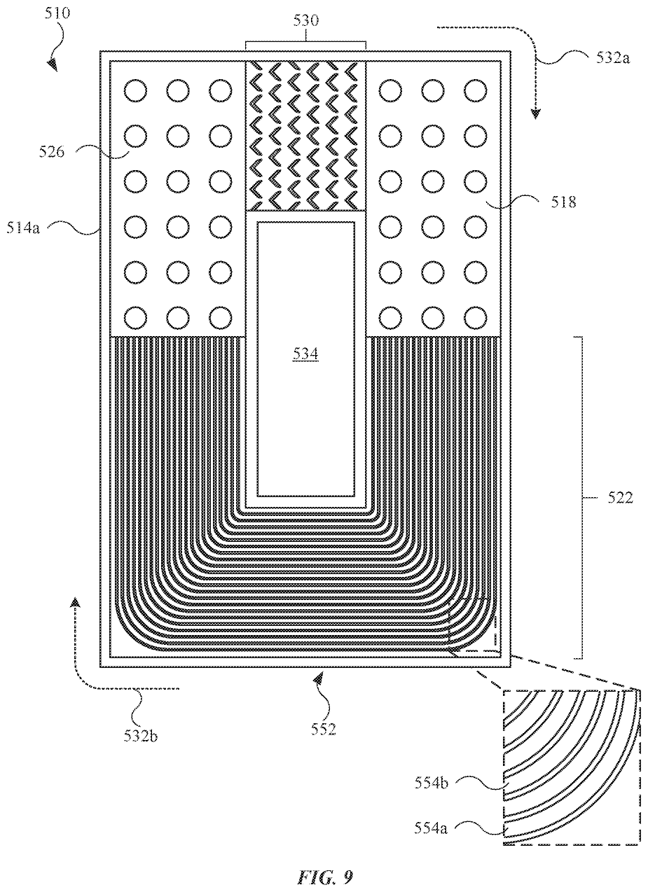

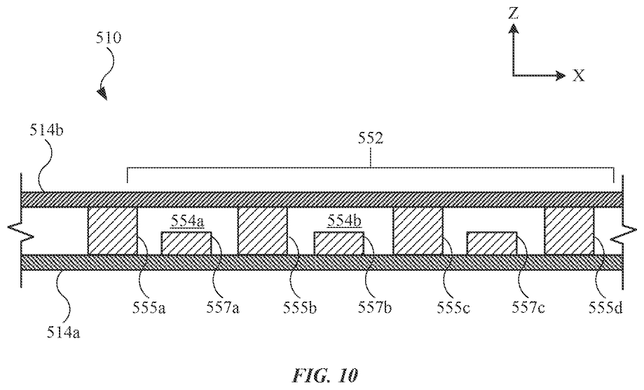

Referring to FIG. 9, a thermal module 510 with several channels is shown. Thermal module 510 may include a part 514a. For purposes of illustration, an additional part, acting as a cover, may couple to part 514a. Thermal module 510 may further include an evaporator section 518, a condensation section 526, an intermediate section 522 coupled to evaporator section 518 and condensation section 526, and flow barriers 530 between evaporator section 518 and condensation section 526. Additionally, intermediate section 522 may include channels 552. For example, as shown in the enlarged view, intermediate section 522 includes a channel 554a and a channel 554b (representative of additional channels). Each of channels 554a and 554b may be formed by two columns (also used as standoffs). Each of channels 554a and 554b may include a width (e.g., between adjacent columns) approximately in the range of 0.1 mm to 0.2 mm. Intermediate section 522 may use channels 552 to drive a refrigerant (not shown in FIG. 10) from evaporator section 518 to condensation section 526. In this regard, channels 552 can drive the refrigerant using capillary forces. Beneficially, channels 552 may take advantage of their shape by using the shape as driving force for a refrigerant. Also, thermal module 510 may include a void 534. Channels may can promote refrigerant flow in a clockwise direction (e.g., in the direction of an arrow 532a and an arrow 532b), causing the refrigerant to circulate around void 534.

Referring to FIG. 10, a cross sectional view of thermal module 510 is shown in a location of channels 552. Thermal module 510 includes a part 514a and a part 514b coupled to part 514a. Channels 552 may include columns with different dimensions (e.g., different heights along a Z-axis). For example, a column 555a, a column 555a, a column 555c, and a column 555d extend from part 514a and engage part 514b, thus supporting part 514b and providing a gap or space between parts 514a and 514b. As shown, columns 555a and 555b may define, in part, channel 554a, and columns 555c and 555d may define, in part, channel 554b. Additionally, a column 557a, a column 557a, and a column 557c extend from part 514a but do not engage part 514b. In this regard, columns 557a, 557a, and 557c may permit flow of a refrigerant over their respective upper surfaces. Based on their respective dimensions, columns 557a, 557b, and 557c are shorter than columns 555a, 555b, 555c, and 555d. As shown in FIG. 10, the ratio of respective heights of each of columns 557a, 557b, and 557c to each of columns 555a, 555b, 555c, and 555d is 1:2 (e.g., a column selected from columns 557a, 557b, and 557c is half of the height as compared to a column selected from columns 555a, 555b, 555c, and 555d). However, in one or more implementations, the ratios are different than 1:2.

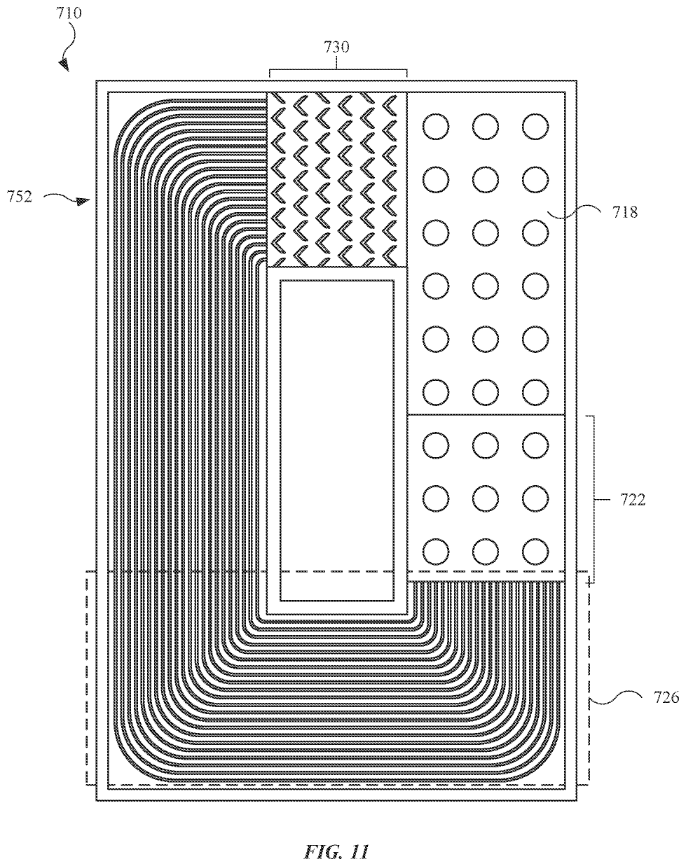

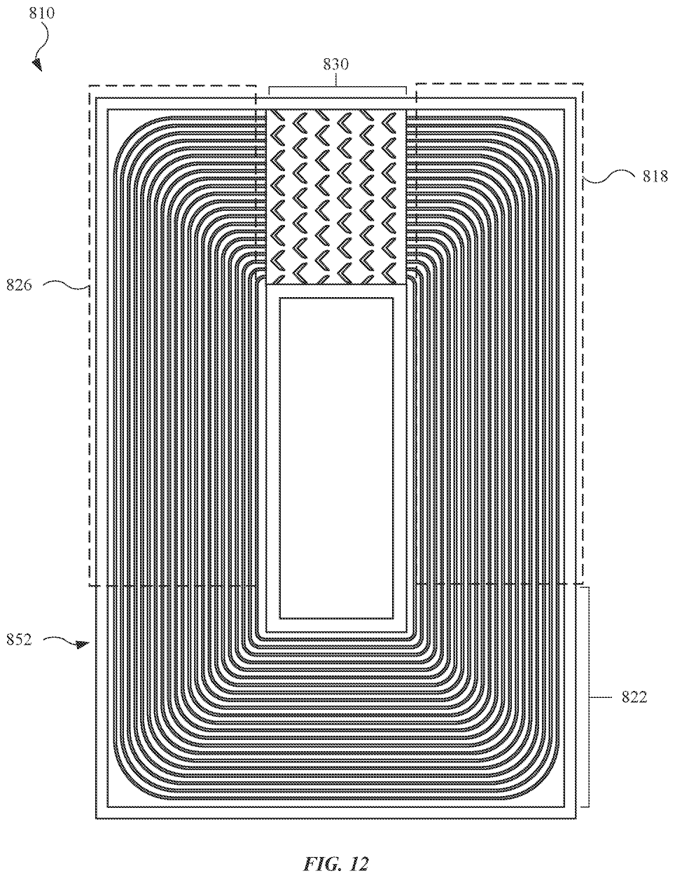

FIGS. 11 and 12 show and describe different examples of thermal modules with a channel in at least one section. The channels shown and described herein may include any features shown and described for the channels 552 in FIGS. 9 and 10, including columns of different heights shown in FIG. 10.

Referring to FIG. 11, an alternate example of a thermal module 710 with several channels is shown. Thermal module 710 may include an evaporator section 718, a condensation section 726, an intermediate section 722 coupled to evaporator section 718 and condensation section 726, and flow barriers 730. Additionally, thermal module 710 may include channels 752. As shown in the example in FIG. 11, channels 752 extend into condensation section 726. As a result, a refrigerant (not shown in FIG. 11) may be driven through condensation section 726 via channels 752 (e.g., by capillary forces). By increasing the area of thermal module 710 dedicated to channels 752, the capillary forces from channels 752 are provided to more locations of thermal module 710, including condensation section 726. This may promote additional fluid flow and/or fluid flow at a greater rate.

Referring to FIG. 12, an alternate example of a thermal module 810 with several channels is shown. Thermal module 810 may include an evaporator section 818, a condensation section 826, an intermediate section 822 coupled to evaporator section 818 and condensation section 826, and flow barriers 830. Additionally, thermal module 810 may include channels 852. As shown in the example in FIG. 12, channels 852 extend into evaporator section 818, intermediate section 522, and condensation section 826. As a result, a refrigerant (not shown in FIG. 12) may be driven through evaporator section 818, intermediate section 522, and condensation section 826 via channels 852 (e.g., by capillary forces). By further increasing the area of thermal module 810 dedicated to channels 852, the capillary forces from channels 852 are provided to more locations of thermal module 810.

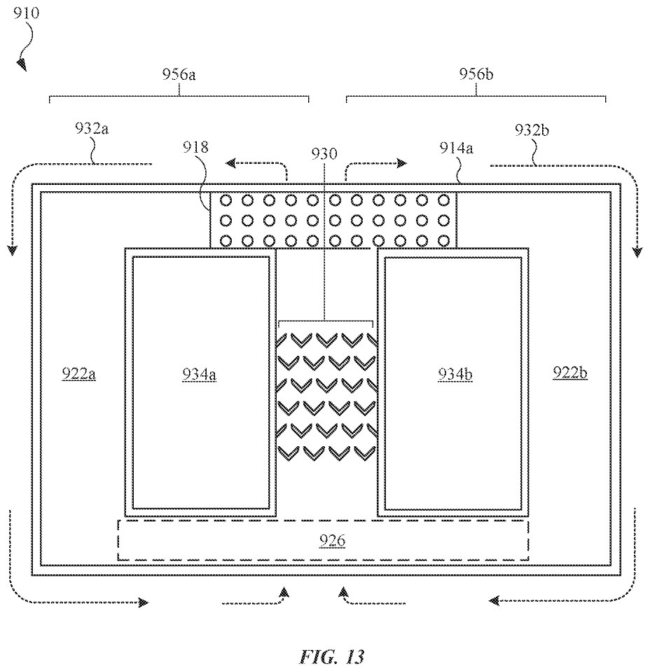

Referring to FIG. 13, a thermal module 910 may include multiple openings. As shown, thermal module 910 includes a part 914a. For purposes of illustration, an additional part, acting as a cover, may couple to part 914a. Thermal module 910 may further include an evaporation section 918 and a condensation section 926. Additionally, thermal module 910 may include an intermediate section 922a and an intermediate section 922b, with each of intermediate sections 922a and 922b being positioned between evaporation section 918 and condensation section 926. Further, thermal module 910 may include flow barriers 930, which may be used as a valve to regulate flow of a refrigerant (not shown in FIG. 13) in a manner previously described.

Thermal module 910 may be characterized as having multiple sections, or regions. For example, thermal module 910 may include a section 956a in which a refrigerant circulates (within thermal module 910) in a counterclockwise direction, as denoted by an arrow 932a (representative of additional arrows in section 956a), around a void 934a of thermal module 910. Additionally, thermal module 910 may include a section 956b in which a refrigerant circulates (within thermal module 910) in a clockwise direction, as denoted by an arrow 932b (representative of additional arrows in section 956b), around a void 934b of thermal module 910. Based on the layout of thermal module 910 and the location and orientation of flow barriers 930, the refrigerant can flow in both a counterclockwise direction in section 956a and a clockwise direction in section 956b. Beneficially, thermal module 910 can drive a refrigerant in different directions, which may allow thermal module 910 to cool multiple heat-generating components (not shown in FIG. 13) at separate and distinct locations within an electronic device.

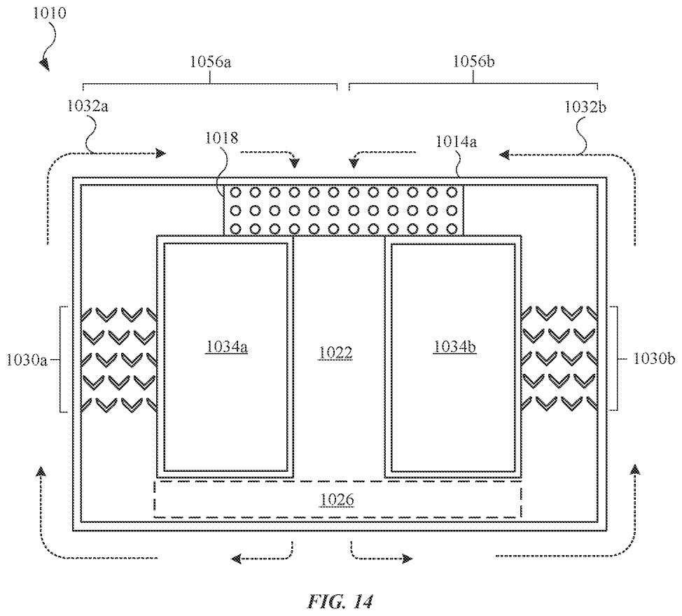

Referring to FIG. 14, an alternate example of thermal module 1010 may include multiple openings. As shown, thermal module 1010 includes a part 1014a. For purposes of illustration, an additional part, acting as a cover, may couple to part 1014a. Thermal module 1010 further includes an evaporation section 1018, an intermediate section 1022, and a condensation section 1026. Additionally, thermal module 1010 may include an intermediate section 1022a, with intermediate section 1022a being positioned between evaporation section 1018 and condensation section 1026. Further, thermal module 1010 may include flow barriers 1030a and flow barriers 1030b, with flow barriers 1030a and flow barriers 1030b representing two separate and distinct sets of flow barriers of thermal module 1010. Each of flow barriers 1030a and flow barriers 1030b may be used as a valve to regulate flow of a refrigerant (not shown in FIG. 14) in a manner previously described.

Thermal module 1010 may be characterized as having multiple regions. For example, thermal module 1010 may include a section 1056a in which a refrigerant circulates (within thermal module 1010) in a clockwise direction, as denoted by an arrow 1032a (representative of additional arrows in section 1056a), around a void 1034a of thermal module 1010. Additionally, thermal module 1010 may include a section 1056b in which a refrigerant circulates (within thermal module 1010) in a counterclockwise direction, as denoted by an arrow 1032b (representative of additional arrows in section 1056b), around avoid 1034b of thermal module 1010. Based on the layout of thermal module 1010 and the respective locations and respective orientations of flow barriers 1030a and flow barriers 1030b, the refrigerant can flow in both a clockwise direction in section 1056a and a counterclockwise direction in section 1056b. Thermal module 1010 may be used to cool multiple heat-generating components (not shown in FIG. 14) at separate and distinct within an electronic device. Moreover, thermal module 1010 can use two sets of flow barriers to regulate flow of a refrigerant in two different directions.

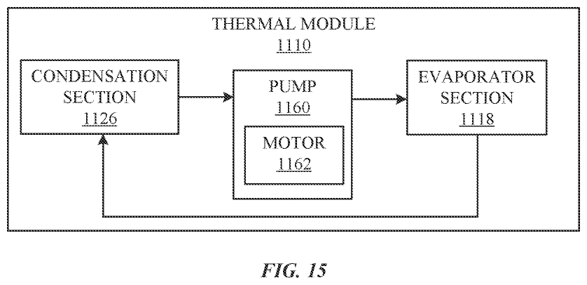

Referring to FIG. 15, a block diagram of a thermal module 1110 is shown. Thermal module 1110 may include an evaporation section 1118, a condensation section 1126, and a pump 1160 coupled to evaporation section 1118 and condensation section 1126. As shown, pump 1160 may include a motor 1162. During operation, pump 1160 is designed to drive, using motor 1162, flow of a refrigerant (not shown in FIG. 15) from condensation section 1126 to evaporation section 1118 (e.g., forward flow), where the refrigerant can be driven in a loop back to condensation section 1126. Further, pump 1160 may have a function similar to the flow barriers described in previous embodiments, and thus prevent back flow (e.g., refrigerant flowing directly from evaporation section 1118 to condensation section 1126 through pump 1160).

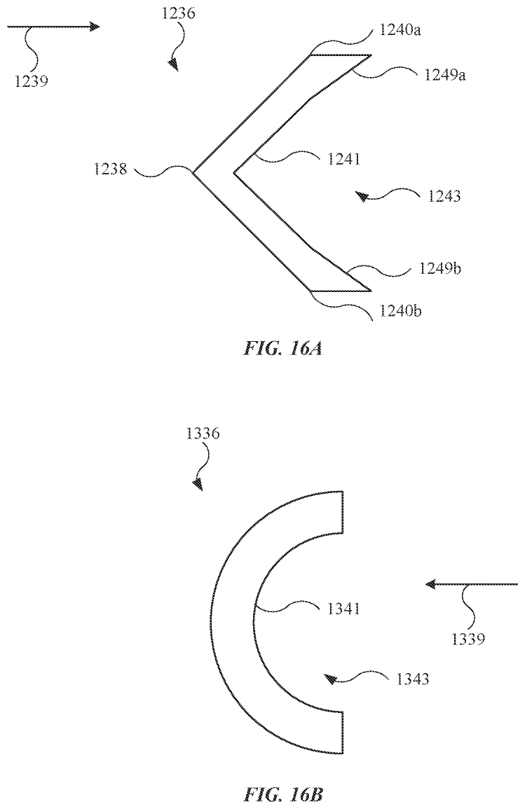

FIGS. 16A and 16B provide alternate examples of flow barriers. The flow barriers shown and described in FIGS. 16A and 16B may substitute for prior examples shown and/or described herein for a flow barrier. Referring to FIG. 16A, a flow barrier 1236 may include an edge 1238, which may be referred to as a leading edge. As shown, edge 1238 may include a relatively sharp apex formed at an intersection of two straight sides or portions of extension of the leading edge. The leading edge 1238 may provide the flow barrier 1236 with a aerodynamically and hydrodynamically favorable shape when flow from a refrigerant (not shown in FIG. 16A) moves along the direction of an arrow 1239.

Additionally, flow barrier 1236 may include a corner 1240a and a corner 1240b, and a trailing edge 1241. As shown, each of corners 1240a and 1240b may include a relatively rounded corner, or smooth corner. Further, flow barrier 1236 may include a tail 1249a and a tail 1249b. Flow barrier 1236a may further include a trailing edge 1241 and a concave portion 1243. When a refrigerant flows into a concave portion 1243, the refrigerant may become trapped, slowed, or otherwise impeded by flow barrier 1236 based on concave portion 1243. Moreover, tails 1249a and 1249b may further enlarge the area and volume of concave portion 1243, thus further trapping, slowing, or otherwise impeding the refrigerant.

Referring to FIG. 16B, a flow barrier 1336 may take the form of a half-circle having a trailing edge 1341 and a concave portion 1343. Flow barrier 1336 may provide a relatively simplified shape, which may facilitate manufacturing of the section of the thermal module containing the flow barriers while still providing concave portion 1343 to trap, slow, or otherwise impede the flow of a refrigerant (not shown in FIG. 16B) that moves along the direction of an arrow 1339.

Various examples of aspects of the disclosure are described below as clauses for convenience. These are provided as examples, and do not limit the subject technology.

Clause A: A thermal module is described. The thermal module may include an enclosure that stores components. The components may include a first section configured to convert a refrigerant to a first state. The components may further include a second section configured to convert the refrigerant to a second state different from the first state. The components may include a plurality of flow barriers including a stationary flow barrier that includes a concave portion. The stationary flow barrier may be configured to: allow the refrigerant to circulate from the first section to the second section, and impede movement of the refrigerant based on the concave portion from the second section to the first section.

Clause B: A thermal module is described. The thermal module may include an enclosure that includes a first housing part and a second housing part coupled with the first housing part. The first housing part and the second housing part may define a void. The thermal module may further include an evaporator section. The thermal module may further include a condensation section. Each of the evaporator section and the condensation section may be configured to change a state of a refrigerant. The thermal module may further include flow barriers positioned between the evaporator section and the condensation section. The flow barriers may be configured to cause the refrigerant to circulate around the void.

Clause C: An electronic device is described. The electronic device may include a heat-generating component. The electronic device may further include a thermal module thermally coupled to the heat-generating component. The thermal module may include an enclosure that stores components. The components may include a first section configured to convert a refrigerant to a first state. The components may further include a second section configured to convert the refrigerant to a second state different from the first state. The components may further include a plurality of flow barriers including a stationary flow barrier that includes a concave portion. The stationary flow barrier may be configured to: allow the refrigerant to circulate from the first section to the second section, and impede movement of the refrigerant based on the concave portion from the second section to the first section.

Clause D: A valve is disclosed. The valve may include a plurality of flow barriers. The plurality of flow barriers may provide a first impedance of flow of a refrigerant in a first direction and a second impedance of flow of the refrigerant in a second direction different from the first direction. The second impedance of flow may be greater than the first impedance of flow. Based on the first impedance of flow and the second impedance of flow, the plurality of flow barriers may bias the refrigerant to flow in the first direction.

One or more of the above clauses can include one or more of the features described below. It is noted that any of the following clauses may be combined in any combination with each other, and placed into a respective independent clause, e.g., clause A, B, C or D.

Clause 1: wherein: the first section is configured to convert the refrigerant to the first state corresponding to a gas state, and the second section is configured to convert the refrigerant from the second state corresponding to a liquid state.

Clause 2: wherein: the enclosure includes a first part and a second part coupled to the first part, and the plurality of flow barriers extend from the first part.

Clause 3: wherein the plurality of flow barriers includes a flow barrier that includes a herringbone shape.

Clause 4: wherein the plurality of flow barriers includes a flow barrier, the flow barrier including: a leading edge that faces the first section; and a trailing edge, wherein the trailing edge faces the second section.

Clause 5: wherein the plurality of flow barriers includes: a first column of flow barriers, and a second column of flow barriers staggered with respect to the first column of flow barriers.

Clause 6: further including an intermediate section between the first section and the second section, the intermediate section including a plurality of channels configured to transport the refrigerant from the first section to the second section.

Clause 7: wherein the enclosure includes: a rectangular housing; and a void surrounded by the rectangular housing. The stationary flow barrier may be configured to cause the refrigerant to circulate around the void from the first section to the second section.

Clause 8: further including a plurality of channels configured to direct the refrigerant from the evaporator section to the condensation section.

Clause 9: wherein the flow barriers extend from a surface of the first housing part.

Clause 10: wherein the flow barriers contact the second housing part.

Clause 11: wherein the flow barriers do not contact the second housing part.

Clause 12: wherein one or more flow barriers of the flow barriers includes a herringbone shape.

Clause 13: further including a standoff extending from the second housing part and engaging the first housing part.

Clause 14: wherein the evaporator section, the condensation section, and the flow barriers are located between the first housing part and the second housing part.

Clause 15: wherein the plurality of flow barriers extend from a surface of the enclosure.

Clause 16: wherein: the first section includes an evaporator section, and the first section includes a condensation section.

Clause 17: further including an intermediate section between the evaporator section and the condensation section, wherein the plurality of flow barriers is configured to: direct the refrigerant from the evaporator section to the condensation section via the intermediate section, and restrict the refrigerant from directly flowing from the evaporator section to the condensation section.

Clause 18: wherein the plurality of flow barriers includes a flow barrier, the flow barrier including: a leading edge that faces the first direction; and a trailing edge, wherein the trailing edge faces the second direction.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A thermal module, comprising:
an enclosure that stores components, the components comprising:
a first section configured to convert a refrigerant to a first state,
a second section configured to convert the refrigerant to a second state different from the first state, and
a plurality of flow barriers comprising a stationary flow barrier that includes a concave portion, wherein the stationary flow barrier is configured to:
allow the refrigerant to circulate from the first section to the second section, and
impede movement of the refrigerant based on the concave portion from the second section to the first section.

2. The thermal module of claim 1, wherein:
the first section is configured to convert the refrigerant to the first state corresponding to a gas state, and
the second section is configured to convert the refrigerant from the second state corresponding to a liquid state.

3. The thermal module of claim 1, wherein:
the enclosure comprises a first part and a second part coupled to the first part, and
the plurality of flow barriers extend from the first part.

4. The thermal module of claim 1, wherein the plurality of flow barriers comprises a flow barrier that includes a herringbone shape.

5. The thermal module of claim 1, wherein the plurality of flow barriers comprises a flow barrier, the flow barrier comprising:
a leading edge that faces the first section; and
trailing edges, wherein the trailing edges face the second section.

6. The thermal module of claim 1, wherein the plurality of flow barriers comprises:
a first column of flow barriers, and
a second column of flow barriers staggered with respect to the first column of flow barriers.

7. The thermal module of claim 1, further comprising an intermediate section between the first section and the second section, the intermediate section comprising a plurality of channels configured to transport the refrigerant from the first section to the second section.

8. The thermal module of claim 1, wherein the enclosure comprises:
a rectangular housing; and
a void surrounded by the rectangular housing, wherein the stationary flow barrier is configured to cause the refrigerant to circulate around the void from the first section to the second section.

9. A thermal module, comprising:
an enclosure comprising:
a first housing part, and
a second housing part coupled with the first housing part, wherein the first housing part and the second housing part define a void;
an evaporator section;
a condensation section, wherein each of the evaporator section and the condensation section is configured to change a state of a refrigerant; and
flow barriers positioned between the evaporator section and the condensation section, the flow barriers configured to cause the refrigerant to circulate around the void.

10. The thermal module of claim 9, further comprising a plurality of channels configured to direct the refrigerant from the evaporator section to the condensation section.

11. The thermal module of claim 9, wherein the flow barriers extend from a surface of the first housing part.

12. The thermal module of claim 11, wherein the flow barriers contact the second housing part.

13. The thermal module of claim 11, wherein the flow barriers do not contact the second housing part.

14. The thermal module of claim 11, wherein one or more flow barriers of the flow barriers comprises a herringbone shape.

15. The thermal module of claim 9, further comprising a standoff extending from the second housing part and engaging the first housing part.

16. The thermal module of claim 9, wherein the evaporator section, the condensation section, and the flow barriers are located between the first housing part and the second housing part.

17. An electronic device, comprising:
a heat-generating component; and
a thermal module thermally coupled to the heat-generating component, the thermal module comprising:
an enclosure that stores components, the components comprising:
a first section configured to convert a refrigerant to a first state,
a second section configured to convert the refrigerant to a second state different from the first state, and
a plurality of flow barriers comprising a stationary flow barrier that includes a concave portion, wherein the stationary flow barrier is configured to:
allow the refrigerant to circulate from the first section to the second section, and
impede movement of the refrigerant based on the concave portion from the second section to the first section.

18. The electronic device of claim 17, wherein the plurality of flow barriers extend from a surface of the enclosure.

19. The electronic device of claim 17, wherein:
the first section comprises an evaporator section, and
the first section comprises a condensation section.

20. The electronic device of claim 19, further comprising an intermediate section between the evaporator section and the condensation section, wherein the plurality of flow barriers is configured to:
direct the refrigerant from the evaporator section to the condensation section via the intermediate section, and
restrict the refrigerant from directly flowing from the evaporator section to the condensation section.

21. A valve comprising:
a plurality of flow barriers configured to:
provide a first impedance of flow of a refrigerant in a first direction; and
provide a second impedance of flow of the refrigerant in a second direction different from the first direction, wherein:
the second impedance of flow is greater than the first impedance of flow, and
based on the first impedance of flow and the second impedance of flow, the plurality of flow barriers bias the refrigerant to flow in the first direction.

22. The valve of claim 21, wherein the plurality of flow barriers comprises a flow barrier, the flow barrier comprising:
a leading edge that faces the first direction; and
a trailing edge, wherein the trailing edge faces the second direction.
